(19) United States
(12) Patent Application Publication
(10) Pub. No.: US 2009/0197397 A1
(43) Pub. Date: Aug. 6, 2009

(54) Method of Manufacturing Semiconductor Device

(76) Inventors: Eun-Hyun Park, Kyunggi-do (KR); Tae-Kyung Yoo, Kyunggi-do (KR)

Correspondence Address: HARNESS, DICKEY, & PIERCE, P.L.C, 7700 Bonhomme, Suite 400, ST. LOUIS, MO, 63105, US

(21) Appl. No.: 12/083,266

(22) PCT Filed: Oct. 2, 2006
(86) PCT No.: PCT/KR2006/003986

§ 371 Date: Mar. 13, 2009

(30) Foreign Application Priority Data
Oct. 7, 2005 (KR) 10-2005-0094081

(51) Int. Cl. H01L 21/20

(52) U.S. Cl. 438/478; 257/E21.09; 438/46

(57) ABSTRACT

The present invention discloses a method of manufacturing a semiconductor device including a plurality of semiconductor layers grown on a substrate and removing the substrate from the plurality of semiconductor layers. The method of manufacturing the semiconductor device comprises a first step for growing a III-nitride compound semiconductor layer between the substrate and the plurality of semiconductor layers, and a second step for removing the substrate by etching the III-nitride compound semiconductor layer.

### TECHNICAL FIELD

The present invention relates to a method of manufacturing a semiconductor device including a plurality of semiconductor layers grown on a substrate, and removing the substrate from the plurality of semiconductor layers.

### BACKGROUND ART

FIG. 1 is a cross-sectional view illustrating a conventional semiconductor light emitting device, especially, a III-nitride compound semiconductor light emitting device. The III-nitride compound semiconductor light emitting device includes a substrate 100, a buffer layer 200 epitaxially grown on the substrate 100, an n-type nitride compound semiconductor layer 300 epitaxially grown on the buffer layer 200, an active layer 400 epitaxially grown on the n-type nitride compound semiconductor layer 300, a p-type nitride compound semiconductor layer 500 epitaxially grown on the active layer 400, a p-side electrode 600 formed on the p-type nitride compound semiconductor layer 500, a p-side bonding pad 700 formed on the p-side electrode 600, and an n-side electrode 800 formed on the n-type nitride compound semiconductor layer 301 exposed by mesa-etching the p-type nitride compound semiconductor layer 500 and the active layer 400. Here, the III-nitride compound semiconductor means a semiconductor composed of AlₓIn_{y}Ga_{z}N (x+y+z=1).

In the growth of the general nitride compound semiconductor, a sapphire substrate, SiC substrate or Si substrate is used as the substrate 100. Such substrates are basically hetero-substrates from GaN, and very different from GaN in lattice constant, thermal expansion coefficient, and the like. Accordingly, many lattice defects are generated in the nitride compound semiconductor layers grown on the hetero-substrate, which deteriorates the performance of the nitride compound semiconductor device.

After the nitride compound semiconductor layers are grown on the hetero-substrate, very strong strain continuously exists between the nitride compound semiconductor layers. Such strain reduces the lifespan and reliability of the device.

The sapphire substrate has a problem in heat discharge due to low thermal conductivity. It is thus difficult to manufacture a high output device by using the sapphire substrate. The Si substrate has high thermal conductivity, but also has a large lattice parameter difference. Especially in the light emitting device, the Si substrate absorbs generated light.

As a result, the hetero-substrate must be removed to improve the performance of the nitride compound semiconductor device. Researches have been made on a method of removing the hetero-substrate.

Recently, a method of removing the substrate 100 by using a laser has attracted attention. When high output laser beams are radiated through the sapphire substrate 100, the laser beams are absorbed by the low temperature buffer layer 200. As a temperature of the buffer layer 200 rises, thermal decomposition occurs on the buffer layer 200 to separate the nitrogen group from the nitride compound and keep gallium metal, thereby removing the substrate 100.

However, this method requires high-priced laser scan equipment. While the substrate 100 is removed, cracks are generated to reduce a yield.

### DISCLOSURE OF INVENTION

### Technical Problem

The present invention is achieved to solve the above problems. An object of the present invention is to improve reliability and solve a thermal problem in a device, and improve light emitting efficiency in a light emitting device, by easily separating a substrate at a low cost by photoelectrochemical etching.

### Technical Solution

In order to achieve the above-described object of the invention, there is provided a method of manufacturing a semiconductor device including a plurality of semiconductor layers grown on a substrate and removing the substrate from the plurality of semiconductor layers, the method including a first step for sequentially growing a first AlₓIn_{y}Ga_{z}N (x+y+z=1) layer, a second AlₐIn_{b}Ga_{c}N (a+b+c=1) layer and a third AlₑIn_{f}Ga_{g}N (e+f+g=1) layer between the substrate and the plurality of semiconductor layers, and a second step for removing the substrate by etching the second AlₐIn_{b}Ga_{c}N (a+b+c=1) layer.

In the second step, the substrate is removed by etching the second AlₐIn_{b}Ga_{c}N (a+b+c=1) layer through photoelectrochemical etching.

The substrate is removed by selectively etching the second AlₐIn_{b}Ga_{c}N (a+b+c=1) layer through adjusting a light exposure pattern.

The substrate is removed by selectively etching the second AlₐIn_{b}Ga_{c}N (a+b+c=1) layer through light radiation using a slit.

The substrate is removed by selectively etching the second AlₐIn_{b}Ga_{c}N (a+b+c=1) layer through sequential light scanning.

In the first step, the second AlₐIn_{b}Ga_{c}N (a+b+c=1) layer has a higher indium content than the first AlₓIn_{y}Ga_{z}N (x+y+z=1) layer and the third AlₑIn_{f}Ga_{g}N (e+f+g=1) layer (b>y,f).

In the first step, the first AlₓIn_{y}Ga_{z}N (x+y+z=1) layer and the second AlₐIn_{b}Ga_{c}N (a+b+c=1) layer have n-type conductivity.

In the first step, the third AlₑIn_{f}Ga_{g}N (e+f+g=1) layer has n-type conductivity, and the plurality of semiconductor layers further include a p-type AlₕInᵢGaⱼN (h+i+j=1) layer on the third AlₑIn_{f}Ga_{g}N (e+f+g=1) layer.

The method of manufacturing the semiconductor device further includes a third step for removing the p-type AlₕInᵢGaⱼN (h+i+j=1) layer.

In addition, there is provided a method of manufacturing a semiconductor device including a plurality of semiconductor layers grown on a substrate and removing the substrate from the plurality of semiconductor layers, the method including a first step for growing a III-nitride compound semiconductor layer between the substrate and the plurality of semiconductor layers, and a second step for removing the substrate by etching the III-nitride compound semiconductor layer. Here, the III-nitride compound semiconductor means a semiconductor composed of AlₓIn_{y}Ga_{z}N (x+y+z=1).

In the second step, the substrate is removed by etching the III-nitride compound semiconductor layer through photoelectrochemical etching.

The III-nitride compound semiconductor layer contains indium.

The III-nitride compound semiconductor layer has n-type conductivity.

A p-type nitride compound semiconductor layer is further included between the III-nitride compound semiconductor layer and the plurality of semiconductor layers.

The method of manufacturing the semiconductor device further includes a third step for removing the p-type nitride compound semiconductor layer.

### ADVANTAGEOUS EFFECTS

In accordance with the present invention, reliability of the device, especially, external quantum efficiency of the light emitting device can be improved by removing the strain existing in the semiconductor layers, by separating the semiconductor layers grown on a hetero-substrate from the substrate.

### BRIEF DESCRIPTION OF THE DRAWINGS

The present invention will become better understood with reference to the accompanying drawings which are given only by way of illustration and thus are not limitative of the present invention, wherein:

FIG. 1 is a cross-sectional view illustrating one example of a conventional semiconductor light emitting device;

FIG. 2 is a cross-sectional view illustrating thin films of a semiconductor device in accordance with the present invention;

FIG. 3 is a cross-sectional view illustrating a state where metal films and a support substrate are formed to manufacture the semiconductor device in accordance with the present invention;

FIG. 4 is a schematic view illustrating a state where the semiconductor device is put into an etching solution and radiated with ultraviolet rays in accordance with the present invention; and

FIG. 5 is a cross-sectional view illustrating the semiconductor device with its substrate removed in accordance with the present invention.

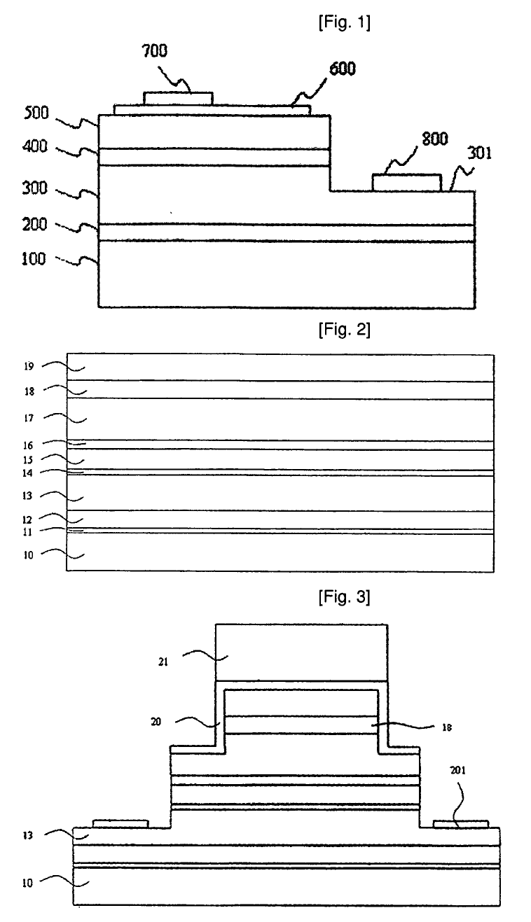

### MODE FOR THE INVENTION

A method of manufacturing a semiconductor device in accordance with preferred embodiments of the present invention will now be described in detail with reference to the accompanying drawings.

FIG. 2 is a cross-sectional view illustrating thin films of the semiconductor device in accordance with the present invention. A buffer layer 11 grown at a low temperature, a non-doped GaN layer 12, a first AlₓIn_{y}Ga_{z}N (x+y+z=1) layer 13 having n-type conductivity, a second AlₐIn_{b}Ga_{c}N (a+b+c=1) layer 14 having n-type conductivity, a third AlₑIn_{f}Ga_{g}N (e+f+g=1) layer 15 having n-type conductivity, a p-type AlₕInᵢGaⱼN (h+i+j=1) layer 16, an n-type nitride compound semiconductor layer 17 on which an n-side electrode is formed, an active layer 18, and a p-type nitride compound semiconductor layer 19 on which a p-side electrode is formed are sequentially stacked on a substrate 10, thereby forming the semiconductor device.

The second AlₐIn_{b}Ga_{c}N (a+b+c=1) layer 14 is selectively etched in photoelectrochemical etching. Therefore, the second AlₐIn_{b}Ga_{c}N (a+b+c=1) layer 14 is etched more fast in the transverse direction than the first AlₓIn_{y}Ga_{z}N (x+y+z=1) layer 13 and the third AlₑIn_{f}Ga_{g}N (e+f+g=1) layer 15, and thus finally completely removed.

In the photoelectrochemical etching, a sample which is an etching object is put into an etching solution, current is supplied thereto with bias, and light is radiated to the sample. Accordingly, only the light-radiated portion is etched. The selective etching etches a specific layer by using an etch rate difference between the nitride compound layers composed of different elements.

In the selective etching, the higher indium content and an n-type doping concentration are, the faster selective etching pregresses, so that the method in accordance with the present invention is easily applicable. However, an excessive indium content deteriorates quality of a thin film grown later. Especially, in the case of a light emitting device, light generated in the active layer 18 is absorbed by the second AlₐIn_{b}Ga_{c}N (a+b+c=1) layer 14 having a high indium content. It results in low light emitting efficiency of the device.

In addition, the first AlₓIn_{y}Ga_{z}N (x+y+z=1) layer 13 uniformly supplies the externally-applied bias, the third AlₑIn_{f}Ga_{g}N (e+f+g=1) layer 15 forms a rough surface region at the lower portion of the device, and the p-type AlₕInᵢGaⱼN (h+i+j=1) layer 16 is doped with Mg, for preventing the active layer 18 from etching.

FIG. 3 is a cross-sectional view illustrating a state where metal films and a support substrate are formed to manufacture the semiconductor device in accordance with the present invention. Referring to FIG. 3, the metal films 20 and 201 and the support substrate 21 are formed after a primary etching process for preventing damages of the active layer 18 of the device in photoelectrochemical etching by protecting the active layer 18 by the metal film 20, and a secondary etching process for uniformly supplying the bias to the device in the photoelectrochemical etching.

The secondary etching process etches at least to the first AlₓIn_{y}Ga_{z}N (x+y+z=1) layer 13. The bias applied through the metal film 21 helps uniform etching and selective etching faster. The metal film 20 deposited on the surface of the device finally serves as an electrode.

The support substrate 21 is a semiconductor substrate such as an Si substrate or a metal plate, and formed on the metal film 20 by bonding or plating. The support substrate 21 must be sufficiently strong to support the succeeding process of manufacturing the device after removal of the substrate 10 on which the semiconductor layers have been grown.

FIG. 4 is a schematic view illustrating a state where the semiconductor device is put into an etching solution and radiated with ultraviolet rays in accordance with the present invention. KOH or H₃PO₄ is used as the etching solution 23, the bias is applied through the metal film 201, and the ultraviolet rays 22 are radiated by an ultraviolet lamp or ultraviolet laser.

In the ultraviolet radiation, if the ultraviolet rays 22 are uniformly radiated to the whole substrate 10, since the ultraviolet rays 22 are continuously radiated to the portion etched by the photoelectrochemical etching, the upper semiconductor layer may be damaged by etching. To solve the above problem, the ultraviolet rays 22 must be selectively radiated to the portion which is being etched or will be etched. That is, the portion of the semiconductor layer separated from the substrate 10 must be protected from the ultraviolet rays 22 not to be etched more.

The light can be selectively partially radiated by designing a light exposure pattern of the light source in a linear or circular shape and so on. In the case of the linear light exposure pattern, the light source is moved to sequentially scan the device, and in the case of the circular light exposure pattern, the light source is sequentially concentrated on the center of the device. In the case that uniform light with large area is used, the light can be selectively radiated to a specific portion by installing a slit on the device. Laser scanning can also be used.

Preferably, tensile strain is formed in the first AlₓIn_{y}Ga_{z}N (x+y+z=1) layer 13 and the third AlₑIn_{f}Ga_{g}N (e+f+g=1) layer 15. During the etching, the etched portion is slightly bent upwardly, so that the etching solution 23 can easily penetrate into the device and facilitate etching.

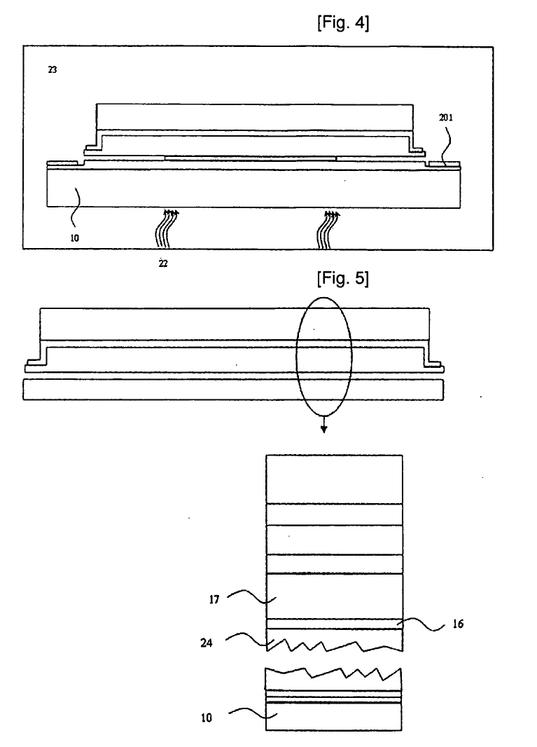

FIG. 5 is a cross-sectional view illustrating the semiconductor device with its substrate removed in accordance with the present invention. A rough surface 24 is formed by etching at the lower portion of the device. The rough surface 24 serves to improve external quantum efficiency in the light emitting device. After the substrate 10 is removed, the p-type AlₕInᵢGaⱼN (h+i+j=1) layer 16 is removed by dry etching, and the n-side electrode is formed on the n-type nitride compound semiconductor layer 17, thereby manufacturing the semiconductor device.

The method of manufacturing the semiconductor device which removes the substrate 10 by the photoelectrochemical etching is applicable not only to the semiconductor light emitting device but also to a light receiving device and an electronic device.

Although the preferred embodiments of the present invention have been described, it is understood that the present invention should not be limited to these preferred embodiments but various changes and modifications can be made by one skilled in the art within the spirit and scope of the present invention as hereinafter claimed.

1. A method of manufacturing a semiconductor device including a plurality of semiconductor layers grown on a substrate and removing the substrate from the plurality of semiconductor layers, the method comprising:
a first step for sequentially growing a first AlₓIn_{y}Ga_{z}N (x+y+z=1) layer, a second AlₐIn_{b}Ga_{c}N (a+b+c=1) layer and a third AlₑIn_{f}Ga_{g}N (e+f+g=1) layer between the substrate and the plurality of semiconductor layers; and
a second step for removing the substrate by etching the second AlₐIn_{b}Ga_{c}N (a+b+c=1) layer.

2. The method of claim 1,
wherein, in the second step, the substrate is removed by etching the second AlₐIn_{b}Ga_{c}N (a+b+c=1) layer through photoelectrochemical etching.

3. The method of claim 2,
wherein the substrate is removed by selectively etching the second AlₐIn_{b}Ga_{c}N (a+b+c=1) layer through adjusting a light exposure pattern.

4. The method of claim 2,
wherein the substrate is removed by selectively etching the second AlₐIn_{b}Ga_{c}N (a+b+c=1) layer through light radiation using a slit.

5. The method of claim 2,
wherein the substrate is removed by selectively etching the second AlₐIn_{b}Ga_{c}N (a+b+c=1) layer through sequential light scanning.

6. The method of claim 1,
wherein, in the first step, the second AlₐIn_{b}Ga_{c}N (a+b+c=1) layer has a higher indium content than the first AlₓIn_{y}Ga_{z}N (x+y+z=1) layer and the third AlₑIn_{f}Ga_{g}N (e+f+g=1) layer (b>y,f).

7. The method of claim 1,
wherein, in the first step, the first AlₓIn_{y}Ga_{z}N (x+y+z=1) layer and the second AlₐIn_{b}Ga_{c}N (a+b+c=1) layer have n-type conductivity.

8. The method of claim 1,
wherein, in the first step, the third AlₑIn_{f}Ga_{g}N (e+f+g=1) layer has n-type conductivity, and the plurality of semiconductor layers further comprise a p-type AlₕInᵢGaⱼN (h+i+j=1) layer on the third AlₑIn_{f}Ga_{g}N (e+f+g=1) layer.

9. The method of claim 8,
further comprising a third step for removing the p-type AlₕInᵢGaⱼN (h+i+j=1) layer.

10. A method of manufacturing a semiconductor device including a plurality of semiconductor layers grown on a substrate and removing the substrate from the plurality of semiconductor layers, the method comprising:
a first step for growing a III-nitride compound semiconductor layer between the substrate and the plurality of semiconductor layers; and
a second step for removing the substrate by etching the III-nitride compound semiconductor layer.

11. The method of claim 10,
wherein, in the second step, the substrate is removed by etching the III-nitride compound semiconductor layer through photoelectrochemical etching.

12. The method of claim 11,
wherein the III-nitride compound semiconductor layer contains indium.

13. The method of claim 11,
wherein the III-nitride compound semiconductor layer has n-type conductivity.

14. The method of claim 11,
wherein a p-type nitride compound semiconductor layer is further included between the III-nitride compound semiconductor layer and the plurality of semiconductor layers.

15. The method of claim 14,
further comprising a third step for removing the p-type nitride compound semiconductor layer.
